(19) United States
(12) Patent Application Publication
(10) Pub. No.: US 2013/0161804 A1
(43) Pub. Date: Jun. 27, 2013

(54) INTEGRATED CIRCUIT (IC) LEADFRAME DESIGN

(71) Applicants: Clifford R. Fishley, San Jose, CA (US); John J. Krantz, Northampton, PA (US); Abiola Awujoola, Pleasanton, CA (US); Allen S. Lim, San Jose, CA (US); Stephen M. King, Hamburg, PA (US); Lawrence W. Golick, Nazareth, PA (US)

(72) Inventors: Clifford R. Fishley, San Jose, CA (US); John J. Krantz, Northampton, PA (US); Abiola Awujoola, Pleasanton, CA (US); Allen S. Lim, San Jose, CA (US); Stephen M. King, Hamburg, PA (US); Lawrence W. Golick, Nazareth, PA (US)

(21) Appl. No.: 13/333,294

(22) Filed: Dec. 21, 2011

(51) Int. Cl. H01L 23/495; H01L 21/00

(52) U.S. Cl. 257/676; 29/827; 257/E23.052

(57) ABSTRACT

Provided, in one embodiment, is an integrated circuit (IC) leadframe. In one example, the leadframe includes a paddle, wherein the paddle has a surface configured to accept an IC chip and has at least one edge. In this example, the leadframe may further include a plurality of lead fingers having ends extending toward the at least one edge, wherein the ends of ones of adjacent lead fingers are staggered proximate and distal the at least one edge.

### TECHNICAL FIELD

This application is directed, in general, to an integrated circuit (IC) leadframe and, more specifically, to an IC leadframe having staggered lead fingers.

### BACKGROUND

Wire-bonding technology for integrated circuit packages remains a staple in IC manufacturing. For high pin count devices with fine pitch it allows an element of precision that is difficult to match with flip-chip solder bump technology. Typical high-pin count packages, for example thin quad flat pack TQFP packages, have a square or rectangular paddle, on which the IC chip is bonded, with leads extending from the four sides. In state-of-the-art high-speed digital devices the length and configuration of the wire bonds and the leadframe fingers to which the wire bonds are attached adds a circuit element that needs to be controlled for optimum performance. A variety of leadframe designs have been developed to address these issues but improvements are continually sought.

### SUMMARY

One aspect provides an integrated circuit (IC) leadframe. In one example, the leadframe includes a paddle, wherein the paddle has a surface configured to accept an IC chip and has at least one edge. In this example, the leadframe may further include a plurality of lead fingers having ends extending toward the at least one edge, wherein the ends of ones of adjacent lead fingers are staggered proximate and distal the at least one edge.

Another aspect provides a method for manufacturing an IC leadframe. In one example, the method includes forming a paddle, wherein the paddle has a surface configured to accept an IC chip and has at least one edge. In this example, the method further includes creating a plurality of lead fingers having ends extending toward the at least one edge, wherein the ends of ones of adjacent lead fingers are staggered proximate and distal the at least one edge.

Yet another aspect provides an IC package. In one example, the IC package includes: 1) a paddle having at least one edge, 2) an IC chip secured to a surface of the paddle, 3) a plurality of lead fingers having ends extending toward the at least one edge, wherein the ends of ones of adjacent lead fingers are staggered proximate and distal the at least one edge, and 4) a plurality of wire bonds electrically connecting the plurality of lead fingers to bond pads of the IC chip.

### BRIEF DESCRIPTION

Reference is now made to the following descriptions taken in conjunction with the accompanying drawings, in which:

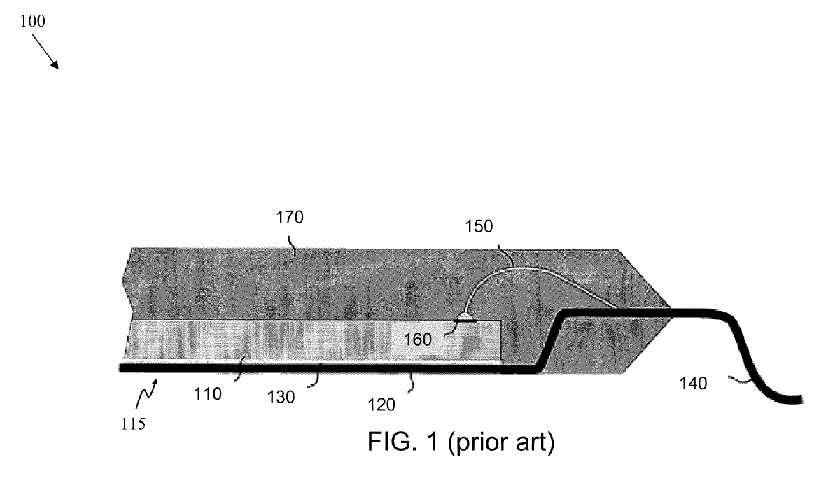

FIGS. 1-4 illustrate various different views of Prior Art integrated circuit (IC) packages;

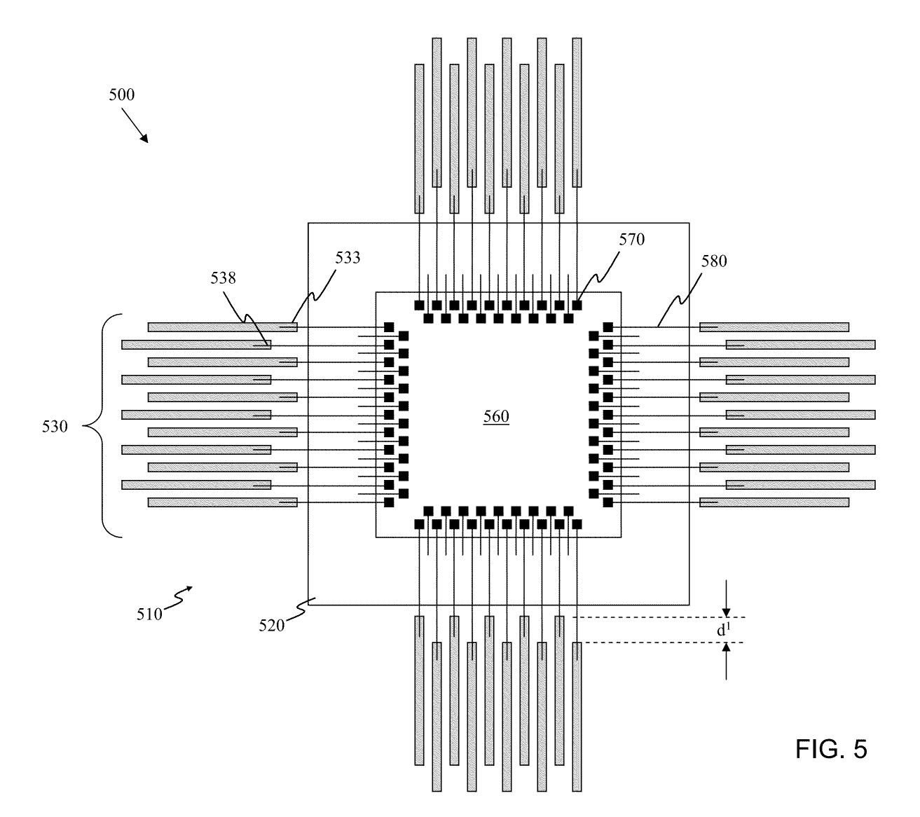

FIG. 5 illustrates a plan view of one embodiment of an IC package manufactured in accordance with the disclosure;

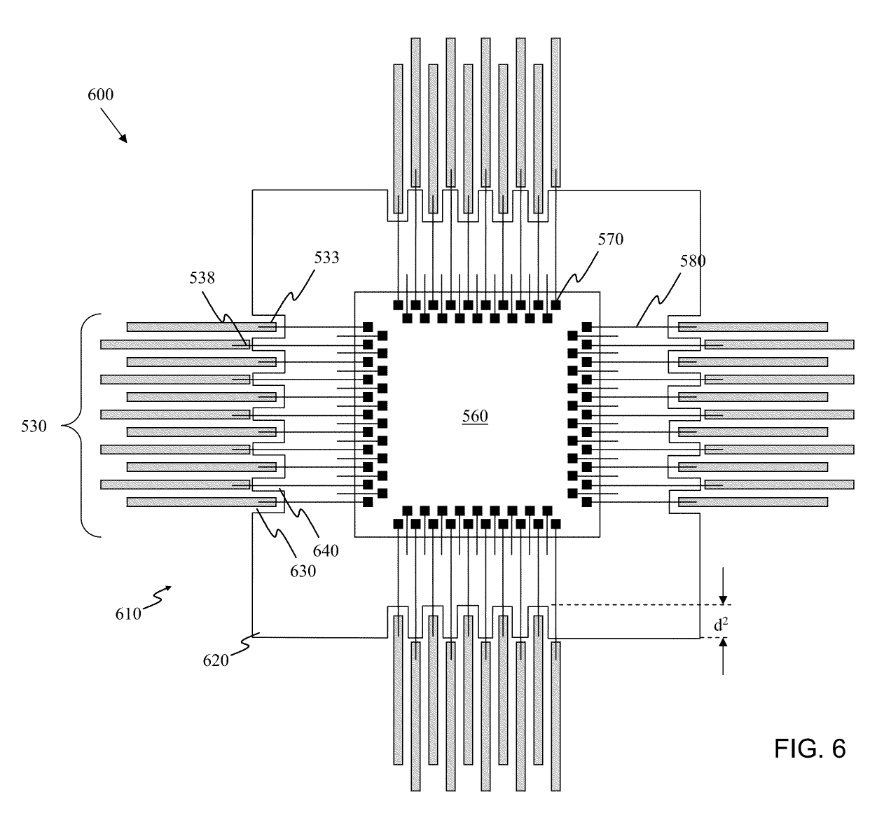

FIG. 6 illustrates a plan view of another embodiment of an IC package manufactured in accordance with the disclosure;

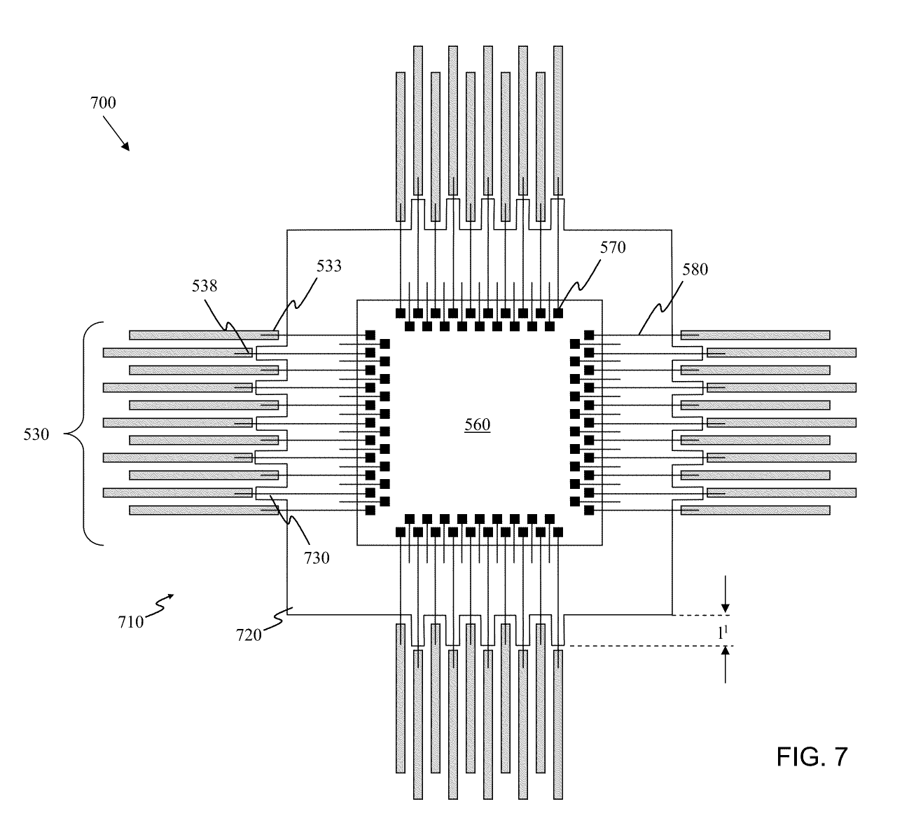

FIG. 7 illustrates a plan view of yet another embodiment of an IC package manufactured in accordance with the disclosure;

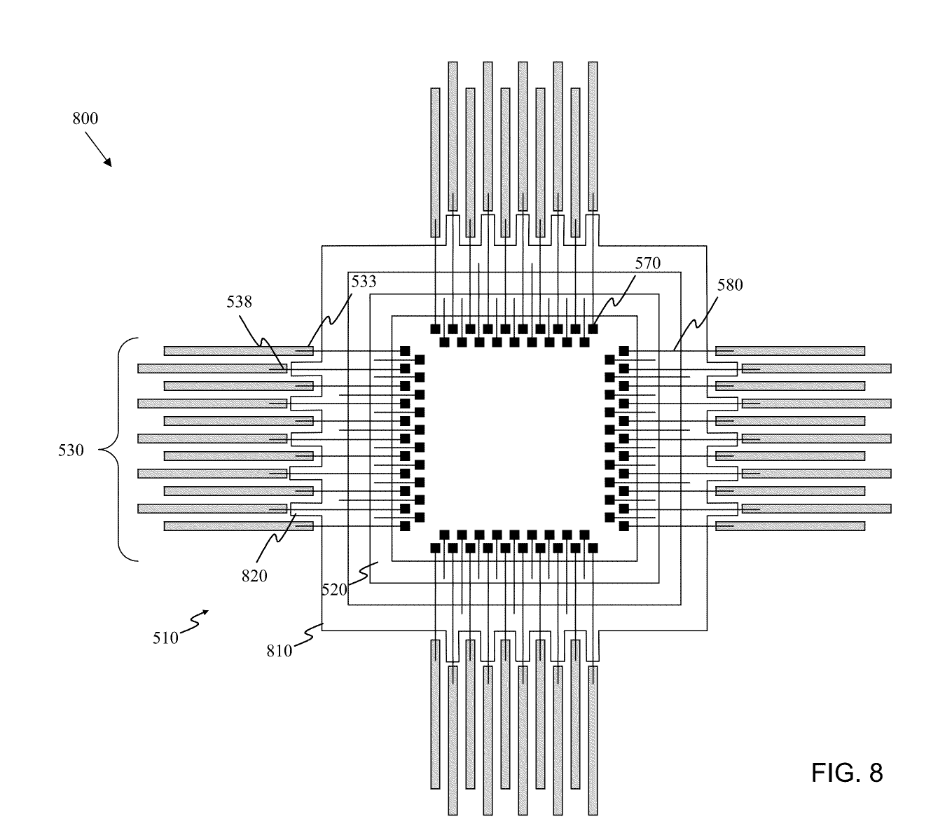

FIG. 8 illustrates a plan view of another embodiment of an IC package manufactured in accordance with the disclosure;

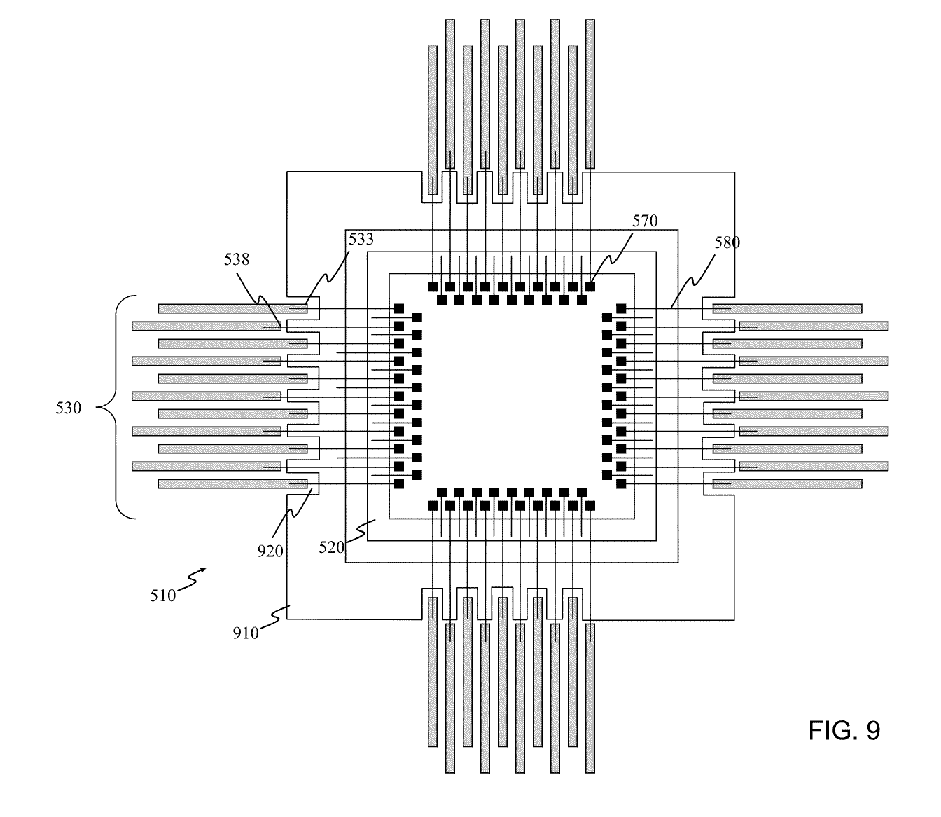

FIG. 9 illustrates a plan view of another embodiment of an IC package manufactured in accordance with the disclosure; and

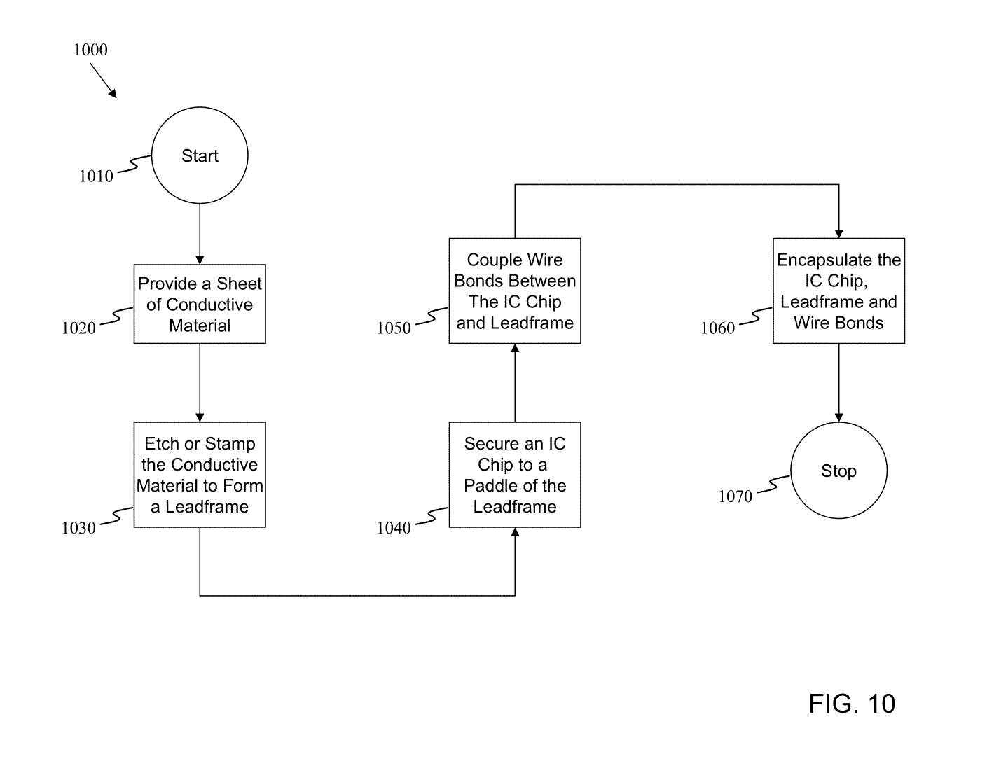

FIG. 10 illustrates a flow diagram of one process for manufacturing an IC package in accordance with the disclosure.

### DETAILED DESCRIPTION

The present disclosure is based, at least in part, on the acknowledgment that as IC data communication rates increase, it becomes increasingly difficult to maintain signal integrity. For example, as the chip data rates increase, the rate of change of voltage with respect to time (dv/dt) also increases. With rising dv/dt, there is increased induction of unwanted signals on adjacent nets in the package, creating crosstalk. The induced crosstalk on a given net distorts the original signal of that net. Accordingly, as the distortion increases, the receiving circuit is less able to detect a logic 1 or a logic 0, and data corruption may occur.

Based upon the foregoing acknowledgement, the present disclosure recognizes that by staggering the lead fingers of a leadframe of an IC package (e.g., as shown in FIGS. 5-9), reduced crosstalk may be achieved. For example, the staggering of the lead fingers can create a situation wherein the associated bond wires are physically spaced further apart from one another. This increased physical spacing may exist in both the horizontal direction, as well as the vertical direction.

The present disclosure has further recognized that by including slots (e.g., as shown in the embodiments of FIGS. 6 and 9), or including posts (e.g., as shown in the embodiments of FIGS. 7 and 8), even greater reduction in crosstalk may be realized. Accordingly, the inclusion of the staggered lead fingers and/or slots or posts, allows an IC package (e.g., such as those shown in FIGS. 5-9) to greatly extend the upper data rate limits thereof, in contrast to the prior art designs (e.g., such as those shown in FIGS. 1-4). Moreover, the upper data rate limits may be achieved without decreasing the I/O count.

The disclosure will be illustrated and described using an exposed paddle thin quad flat pack integrated circuit (IC) package (eTQFP) as a prototype. However, it should be understood that the disclosure is not so limited. It may apply to a variety of wire-bonded IC devices. Typically these will be overmolded plastic packages, as in the example illustrated here, or may be plastic cavity packages, or any other type of high pin count packaging. Also considered within the scope of the disclosure are IC or electrical component packages in which the configuration is modified to influence other aspects of the electrical performance of the device. The package may contain hybrid ICs or integrated passive device (IPD) chips. It may also contain optical sub-assemblies such as MEMS devices packaged with digital chips.

With reference to FIG. 1, illustrated is a prior art integrated circuit (IC) package 100. The IC package 100, as shown, includes a IC chip 110 bonded to a leadframe 115. The leadframe 115 comprises a paddle 120 with solder, or conductive adhesive, 130 as the medium for bonding the IC chip 110 to the paddle 120. In this package design, the paddle 120 is exposed on the bottom of the package to allow a ground I/O connection to be made directly to the exposed paddle 120. The leadframe 115 also comprises lead fingers 140 extending from the side of the package toward the paddle 120. This form of semiconductor device package is characterized by wire bonds 150 bonded between bond pads 160 on the IC chip 110 and the lead fingers 140. FIG. 1 also illustrates a plastic encapsulant 170.

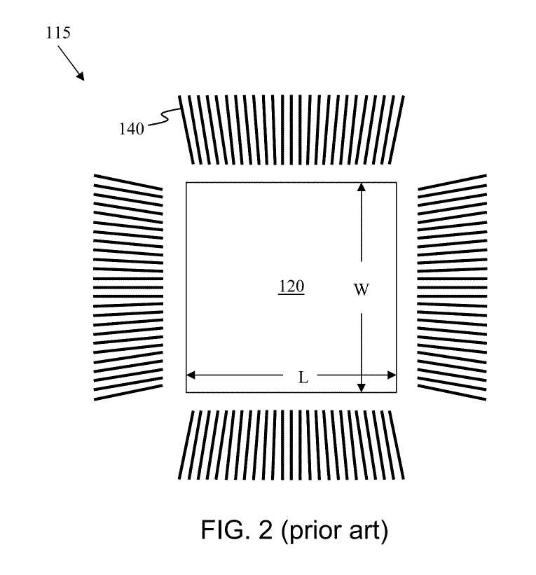

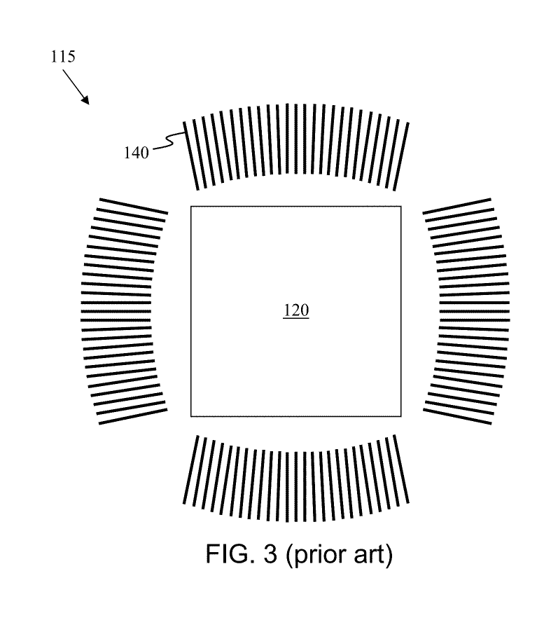

FIG. 2 is a plan view of the leadframe 115 of FIG. 1 that schematically shows the organization of the lead fingers 140 that extend toward the paddle 120. The lead fingers 140 in this design are fanned. The fanned array provides approximately equal wire bonds lengths. The paddle 120 typically has a square shape, with four edges as shown. In the general case the paddle has a quadrilateral shape, with length L, width W, and four edges. In FIG. 2, the plurality of lead fingers 140 extends toward the paddle 120 along the four edges. Other designs are possible, but the lead fingers 140 will often extend toward at least two edges. FIG. 3 illustrates a leadframe similar to that of FIG. 2; however, in this example the lead fingers 140 are curved about each side of the leadframe 115.

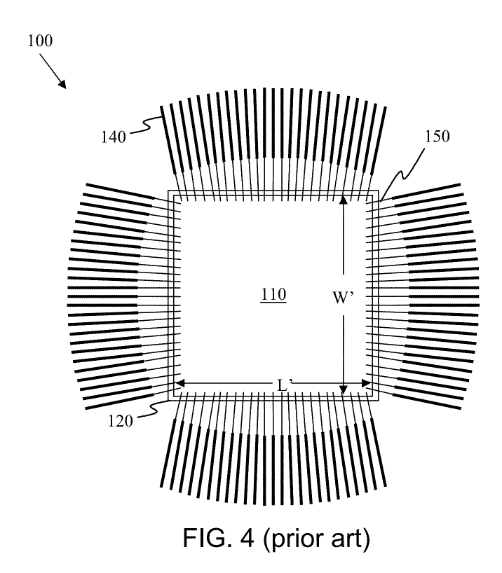

FIG. 4 illustrates the leadframe of FIG. 3 with the IC chip 110 die bonded to the paddle 120. The IC chip 110 in this design, has a square shape but, again, in the general case the IC chip has a quadrilateral shape with length L′, width W′, wherein L′ is less than L (of the paddle 120) and W′ is less than W (of the paddle 120), and wherein the IC chip 110 substantially covers the paddle 120 except for the exposed regions along the edge of the paddle 120. (The exposed regions are a consequence of L′ and W′ being less than L and W, respectively.) FIG. 4 also shows the wire bonds 150 between the IC chip 110 and the lead fingers 140. Due to the fanning of the lead fingers, and the curved configuration of the array of lead fingers, the length of all of the wire bonds in the array is approximately equal.

FIG. 5 illustrates a plan view of one embodiment of an IC package 500 manufactured in accordance with the disclosure. The IC package 500 illustrated in the embodiment of FIG. 5 initially includes an IC leadframe 510. In the example embodiment of FIG. 5, the IC leadframe 510 includes a paddle 520. The term “paddle” as used herein, is a well known term in the art designed to reference a surface upon which an IC chip is bonded. The paddle 520, in the embodiment of FIG. 5, includes at least one edge. For example, the paddle 520 illustrated in the embodiment of FIG. 5 is quadrilateral in shape, and thus has four edges. As those skilled in the art are aware, the paddle 520 may be electrically coupled to a ground pin, voltage pin, etc. and remain within the purview of the disclosure. In the particular embodiment of FIG. 5, the paddle 520 is electrically connected to a ground pin.

The leadframe 510 illustrated in FIG. 5 further includes a plurality of lead fingers 530. The plurality of lead fingers 530 have ends that extend toward one or more edges of the paddle 520. In the illustrated embodiment of FIG. 5, the ends of the plurality of lead fingers 530 extend toward all four sides of the paddle 520. Nevertheless, other embodiments may exist wherein the ends of the plurality of lead fingers 530 extend toward fewer than all sides of the paddle 520.

In accordance with the disclosure, the lead fingers 530 may be alternately staggered along one or more edges of the paddle 520. The term “alternately staggered”, as used herein, is intended to exclude those configurations such as shown in FIGS. 2 and 3, wherein the lead fingers are fanned and/or curved. To be “alternately staggered”, three adjacent lead fingers 530 must include one in a position proximate the paddle 520 edge and two in positions distal the paddle 520 edge, or alternatively one in a position distal the paddle 520 edge and two in positions proximate the paddle 520 edge. Accordingly, a single lead finger 530 must be staggered forward or back relative to its adjacent two lead fingers, to be “alternately staggered” in accordance with the disclosure.

In the embodiment of FIG. 5, ones of adjacent lead fingers 530 are alternately staggered proximate and distal at least one edge of the paddle 520. For instance, proximate staggered lead fingers 533 are closer to the edge of the paddle 520 than distal staggered lead fingers 538. In the embodiment of FIG. 5, the lead fingers 530 are alternately staggered across the entire length of the one or more edges of the paddle 520. In an alternative embodiment, however, less than all of the lead fingers 530 that extend toward a given edge of the paddle 520 are alternately staggered. Furthermore, the lead fingers 530 need not be alternately staggered along each of the four sides of the paddle 520.

The degree of stagger amongst adjacent lead fingers 530 will likely depend on the design of the leadframe 510. Nevertheless, certain embodiments exist wherein adjacent lead fingers 530 will be staggered from one another by a distance (d¹) ranging from about 0.4 mm to about 1.5 mm, and in another particular embodiment a distance (d¹) ranging from about 0.5 mm to about 1.0 mm. It should be noted that the distance (d¹) of stagger need not be fixed across the entire IC package 500, or for that matter across an entire side of the leadframe 510. Accordingly, embodiments may exist wherein the distance (d¹) varies within the IC package 500. As disclosed above, the inclusion of the staggered lead fingers reduces crosstalk within the IC package 500.

Secured to the paddle 520 in the embodiment of FIG. 5 is an IC chip 560. The IC chip 560, in one embodiment, might be an IC chip as used in disk drive SoC's (system on chip) and gigabit PHY interface devices, among others. The IC chip 560, in the particular embodiment shown, may include bond pads 570. Additionally, a plurality of wire bonds 580 may electrically connect the lead fingers 530 to the bond pads 570. As additionally shown, the wire bonds 580 may also electrically connect the paddle 520 to various bond pads 570 of the IC chip 560.

Turning now to FIG. 6, illustrated is a plan view of an alternative embodiment of an IC package 600 manufactured in accordance with the disclosure. The IC package 600 illustrated in FIG. 6 is similar in many respects to the IC package 500 illustrated in FIG. 5. Accordingly, like reference numbers are being used to illustrate like features. A major difference between the IC package 500 of FIG. 5 and the IC package 600 of FIG. 6 resides in the differences between the leadframe 510 and leadframe 610, and their associated paddles. For example, the paddle 620 of the IC package 600 of FIG. 6 is provided with one or more slots 630. The term “slot”, as used herein, is intended to convey an indentation into the general footprint of the structure (e.g., the generally square shaped paddle 620). In the particular embodiment shown, the one or more slots 630 extend into the paddle 620, and correspond with the proximate staggered lead fingers 533. For example, ones of the proximate staggered lead fingers 533 extend into the corresponding slots 630.

The slots 630 need not exist on all sides of the paddle 620. For example, other embodiments may exist wherein the slots 630 are located on less than all sides of the paddle 620. Additionally, the slots 630 need not extend along the entire length of the sides that they are located. For example, the slots 630 might be located proximate the corners of any one side of the paddle 620, thus leaving the center of that one side without the slots 630. Alternatively, the slots 630 could be located in the center of any one side of the paddle 620, as well as in other locations.

Generally, the number, location and size of the slots 630 will correspond to the staggering of the one or more lead fingers 530. For example, the number and location of the slots 630 will typically correspond to the number and location of the proximate staggered lead fingers 533. Additionally, the size of the slots 630, and more particularly the depth (d²) of the slots 630, will correspond to the distance (d¹) of the stagger of the lead fingers 530. For example, in one embodiment the depth (d²) is slightly greater than the distance (d¹). Nonetheless, other correlations between the depth (d²) and the distance (d¹) may exist.

The slots 630, such as those shown in FIG. 6, by nature tend to create spokes 640 that separate adjacent ones of proximate staggered lead fingers 533. Accordingly, the spokes 640 tend to provide electrical shielding between the separate adjacent ones of proximate staggered lead fingers 533. The electrical shielding provided by the spokes 640 is believed to significantly reduce crosstalk between the lead fingers 533 themselves, as well as between the lead fingers 533 and the wire bonds 580.

Turning briefly to FIG. 7, illustrated is a plan view of an alternative embodiment of an IC package 700 manufactured in accordance with the disclosure. The IC package 700 illustrated in FIG. 7 is similar in many respects to the IC package 500 illustrated in FIG. 5. Accordingly, like reference numbers are being used to illustrate like features. A major difference between the IC package 500 of FIG. 5 and the IC package 700 of FIG. 7 resides in the differences between the leadframe 510 and leadframe 710, and their associated paddles. For example, the paddle 720 of the IC package 700 of FIG. 7 is provided with one or more posts 730. The term “post,” as used herein, is intended to convey a protrusion from the general footprint of the structure it is extending away from (e.g., the generally square shaped paddle 720). In the particular embodiment shown, the one or more posts 730 correspond with the distal staggered lead fingers 538. Accordingly, the one or more posts 730 separate adjacent ones of the proximate staggered lead fingers 533.

The posts 730 need not exist on all sides of the paddle 720. For example, other embodiments may exist wherein the posts 730 are located on less than all sides of the paddle 720. Additionally, the posts 730 need not extend along the entire length of the sides that they are located. For example, the posts 730 might be located proximate the corners of any one side of the paddle 720, thus leaving the center of that one side without the posts 730. Alternatively, the posts 730 could be located in the center of any one side of the paddle 720, as well as in other locations.

Generally, the number, location and size of the posts 730 will correspond to the staggering of the one or more lead fingers 530. For example, the number and location of the posts 730 will typically correspond to the number and location of the distal staggered lead fingers 538. Additionally, the size of the posts 730, and more particularly the length (l¹) of the posts 730, will correspond to the distance (d¹) of the stagger of the lead fingers 530. For example, in one embodiment the length (l¹) is slightly greater than the distance (d¹). Nonetheless, other correlations between the length (l¹) and the distance (d¹) may exist.

Turning now to FIG. 8, illustrated is a plan view of an alternative embodiment of an IC package 800 manufactured in accordance with the disclosure. The IC package 800 illustrated in FIG. 8 is similar in many respects to the IC package 500 illustrated in FIG. 5. Accordingly, like reference numbers are being used to illustrate like features. The IC package 800 additionally includes a separate conductive feature 810 positioned between the paddle 520 and the one or more lead fingers 530. The separate conductive feature 810, in one embodiment, is configured as a quite line or static conductor. For example, the separate conductive feature 810 might be configured to carry a static DC voltage, such as power or ground, which would function as a quiet line. The separate conductive feature 810 would not generally be configured to carry an AC signal. Nevertheless, in certain embodiments wherein the AC frequency is low enough, the separate conductive feature 810 carrying an AC signal might function as a quiet line. For example, if the separate conductive feature 810 were configured to carry an AC signal having a frequency below about 60 Hertz, or even below about 45 Hertz in another embodiment, it would likely function as a quiet line for the application of the present disclosure.

In the illustrated embodiment of FIG. 8, the separate conductive feature 810 includes a plurality of posts 820, much the same as the plurality of posts 730 illustrated in the embodiment of FIG. 7. The posts 820, similar to the posts 730 of FIG. 7, are configured to reduce the crosstalk within the device. Nevertheless, wherein the posts 730 of FIG. 7 are located within the paddle 720, the posts 820 are located within the separate conductive feature 810 (e.g., ground ring, power ring, etc.). It should also be noted that while the embodiment of FIG. 8 illustrates the use of posts 820 within the separate conductive feature 810, slots 920 as shown in the embodiment of FIG. 9 could have just as easily been used within the separate conductive feature 910. All such embodiments would experience reduced crosstalk, and thus provide a device capable of higher data rate limits.

Turning briefly to FIG. 10, illustrated is a flow diagram 1000 depicting one process for manufacturing an IC package in accordance with the disclosure. The flow diagram 1000 begins in a start step 1010. Thereafter, in a step 1020, a sheet of conductive material is provided. The sheet of conductive material, as those skilled in the art appreciate, may be any conductive material currently known or hereafter discovered for use in leadframes. In a step 1030, the sheet of conductive material is etched and/or stamped. The step of etching or stamping the sheet of conductive material defines the different features of the leadframe discussed above with regard to FIGS. 5-9. For example, the resulting leadframe might have a paddle with slots or posts, as well as a plurality of lead fingers alternately staggered. Alternatively, the resulting leadframe might have a paddle, a separate conductive feature having slots or posts, as well as the plurality of lead fingers alternately staggered. Those skilled in the art understand the general process for forming the leadframe, as well as that the resulting leadframe may be any configuration consistent with this disclosure.

Thereafter, in a step 1040, an IC chip may be secured to the paddle of the leadframe. Suitable adhesives, whether conductive or not, may be used to secure the IC chip. In a step 1050, wire bonds may be coupled between bond pads on the IC chip and the various different features of the leadframe. For example, certain wire bonds may couple ones of bond pads to the paddle, other wire bonds may couples ones of bond pads to the separate conductive feature, and even other wire bonds may couple ones of bond pads to the alternately staggered lead fingers. Those skilled in the art understand the process for bonding the wire bonds to the various features. Thereafter, in a step 1060, an encapsulant may be formed over the IC chip, leadframe, and wire bonds. The manufacturing process might then end in a stop step 1070.

Various additional modifications (e.g., further additions, deletions, substitutions) of this disclosure may occur to those skilled in the art. All deviations from the specific teachings of this specification that basically rely on the principles and their equivalents through which the art has been advanced are properly considered within the scope of the disclosure as described and claimed.

What is claimed is:

1. An integrated circuit (IC) leadframe, comprising:
a paddle, wherein the paddle has a surface configured to accept an IC chip and has at least one edge; and
a plurality of lead fingers having ends extending toward the at least one edge, wherein the ends of ones of adjacent lead fingers are alternately staggered proximate and distal the at least one edge.

2. The IC leadframe as recited in claim 1, wherein ones of the proximate staggered lead fingers extend into corresponding slots in the paddle.

3. The IC leadframe as recited in claim 1, wherein posts extending from the paddle interpose pairs of the proximate staggered lead fingers.

4. The IC leadframe as recited in claim 1 further including a separate conductive feature positioned between the paddle and the plurality of lead fingers.

5. The IC leadframe as recited in claim 4, wherein ones of the proximate staggered lead fingers extend into corresponding slots in the separate conductive feature.

6. The IC leadframe as recited in claim 4, wherein posts extending from the separate conductive feature interpose pairs of the proximate staggered lead fingers.

7. The IC leadframe as recited in claim 4, wherein the separate conductive feature is a static conductor.

8. The IC leadframe as recited in claim 4, wherein the separate conductive feature is a power ring.

9. The IC leadframe as recited in claim 4, wherein the separate conductive feature is a ground ring.

10. The IC leadframe as recited in claim 1, wherein the paddle has a quadrilateral shape having four edges, and further wherein a plurality of lead fingers having ends extend toward each of the four edges, and further wherein the ends of ones of adjacent lead fingers extending toward each of the four edges are alternately staggered proximate and distal their associated edge.

11. A method for manufacturing an integrated circuit (IC) leadframe, comprising forming a paddle, wherein the paddle has a surface configured to accept an IC chip and has at least one edge; and
creating a plurality of lead fingers having ends extending toward the at least one edge, wherein the ends of ones of adjacent lead fingers are alternately staggered proximate and distal the at least one edge.

12. The method as recited in claim 11 further including placing corresponding slots within the paddle, wherein ones of the proximate staggered lead fingers extend into the corresponding slots.

13. The method as recited in claim 11 further including extending posts from the paddle, the posts interposing pairs of the proximate staggered lead fingers.

14. The method as recited in claim 11 further including positioning a separate conductive feature between the paddle and the plurality of lead fingers.

15. The method as recited in claim 14 further including placing corresponding slots within the separate conductive feature, wherein ones of the proximate staggered lead fingers extend into corresponding slots in the separate conductive feature.

16. The method as recited in claim 14 further including extending posts from the separate conductive feature, the posts interposing pairs of the proximate staggered lead fingers.

17. The method as recited in claim 14 wherein the separate conductive feature is a static conductor.

18. An integrated circuit (IC) package, comprising
a paddle having at least one edge;
an IC chip secured to a surface of the paddle;
a plurality of lead fingers having ends extending toward the at least one edge, wherein the ends of ones of adjacent lead fingers are alternately staggered proximate and distal the at least one edge; and
a plurality of wire bonds electrically connecting the plurality of lead fingers to bond pads of the IC chip.

19. The IC package as recited in claim 18, wherein ones of the proximate staggered lead fingers extend into corresponding slots in the paddle.

20. The IC package as recited in claim 18, wherein posts extending from the paddle interpose pairs of the proximate staggered lead fingers.

21. The IC package as recited in claim 18 further including a separate conductive feature positioned between the paddle and the plurality of lead fingers, and further wherein ones of the proximate staggered lead fingers extend into corresponding slots in the separate conductive feature.

22. The IC package as recited in claim 18 further including a separate conductive feature positioned between the paddle and the plurality of lead fingers, and further wherein posts extending from the separate conductive feature interpose pairs of the proximate staggered lead fingers.
